(19) United States
(12) Patent Application Publication
(10) Pub. No.: US 2022/0181142 A1
(43) Pub. Date: Jun. 9, 2022

(54) METHODS AND APPARATUS FOR PROCESSING A SUBSTRATE

(71) Applicant: APPLIED MATERIALS, INC., Santa Clara, CA (US)

(72) Inventors: Chien-Kang HSIUNG, Taipei (TW); James S. PAPANU, San Rafael, CA (US); Arvind SUNDARRAJAN, Singapore (SG)

(21) Appl. No.: 17/110,940

(22) Filed: Dec. 3, 2020

(51) Int. Cl. H01L 21/02; H01L 21/67; H01L 21/683; H01L 21/687

(52) U.S. Cl. CPC H01L 21/02021; H01L 21/02019; H01L 21/67069; H01L 21/68764; H01L 21/6831; H01L 21/6838; H01L 21/67092

(57) ABSTRACT

Methods and apparatus for far edge trimming are provided herein. For example, an apparatus includes an integrated tool for processing a silicon substrate, comprising a vacuum substrate transfer chamber, an edge trimming apparatus coupled to the vacuum substrate transfer chamber and comprising a high pulse frequency laser and substrate support, wherein at least one of the high pulse frequency laser or the substrate support are movable with respect to each other and configured to trim about 2 mm to about 5 mm from a peripheral edge of a substrate when disposed on the substrate support, and a plasma etching apparatus coupled to the vacuum substrate transfer chamber and configured to etch silicon.

### FIELD

Embodiments of the present disclosure generally relate to a methods and apparatus for processing a substrate. More particularly, to methods and apparatus for far edge substrate trimming.

### BACKGROUND

In semiconductor substrate processing, integrated circuits are formed on a substrate (sometimes referred to as a wafer) composed of silicon or other semiconductor material. In general, layers of various materials which are either semiconducting, conducting, or insulating are used to form integrated circuits upon the substrate. A large number of individual regions, referred to as dies, containing integrated circuits are generally formed on the substrate. Following the integrated circuit formation process, the substrate is diced to separate the individual dies from one another for packaging or for use in an unpackaged form within larger circuits.

Typically, prior to separation of the dies, a substrate thinning process is performed to reduce the size of the individual dies for more efficient die packaging. The inventors have observed that most substrates have a beveled edge that reacts poorly to the mechanical stresses of conventional thinning processes. For example, the inventors have observed that mechanical stresses caused by the substrate thinning process can cause uneven stresses in or on the substrate, thus leading to substrate edge cracking, device damage, or the like. Some conventional substrate edge trimming processes, for example, a grinding wheel polishing process, can be configured to remove the bevel from the substrate edge. However, the inventors have further observed that such processes still apply excessive mechanical force to the substrate, which can damage the substrate, or the layers disposed atop the substrate.

### SUMMARY

Methods and apparatus for far edge substrate trimming are provided herein. In some embodiments an integrated tool for processing a silicon substrate, comprises a vacuum substrate transfer chamber, an edge trimming apparatus coupled to the vacuum substrate transfer chamber and comprising a high pulse frequency laser and substrate support, wherein at least one of the high pulse frequency laser or the substrate support are movable with respect to each other and configured to trim about 2 mm to about 5 mm from a peripheral edge of a substrate when disposed on the substrate support, and a plasma etching apparatus coupled to the vacuum substrate transfer chamber and configured to etch silicon.

In accordance with at least some embodiments, a method for processing a substrate includes trimming an edge of a plurality of stacking layers disposed on a substrate and etching an edge of a bottom layer of silicon exposed by trimming the edge of the plurality of stacking layers.

In accordance with at least some embodiments, a non-transitory computer readable storage medium having instructions stored thereon that, when executed by a processor, cause a method for processing a substrate to be performed. The method includes trimming an edge of a plurality of stacking layers disposed on a substrate and etching an edge of a bottom layer of silicon exposed by trimming the edge of the plurality of stacking layers.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 is a flowchart of a method for processing a substrate in accordance with some embodiments of the present disclosure.

FIG. 2 is a diagram of a system in accordance with some embodiments of the present disclosure.

FIGS. 3A-3E is a sequencing diagram illustrating the operations of the method of FIG. 1 using the system of FIG. 2 in accordance with some embodiments of the present disclosure.

FIG. 4 is a block diagram of an interior volume of a process chamber in accordance with some embodiments of the present disclosure.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of a processing a substrate are provided herein. For example, methods and apparatus described herein are configured for far edge substrate trimming. The methods and apparatus disclosed herein are useful, for example, in substrate edge trimming processes used prior to substrate thinning and dicing processes. For example, the methods and apparatus described herein can include an apparatus configured to provide a protection layer coating, an apparatus configured to provide low heat affected zone (HAZ) laser grooving, which can be programmable or integrated with a rotor table, an apparatus configured to provide silicon plasma etching, and an apparatus configured to provide protection layer cleaning. The methods and apparatus described herein advantageously provide high precision and far edge trimming capability, with little to no stress or mechanical damage being applied to the substrate.

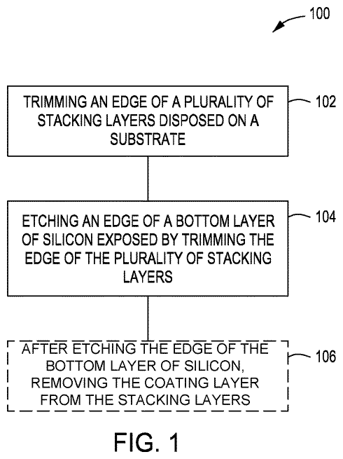

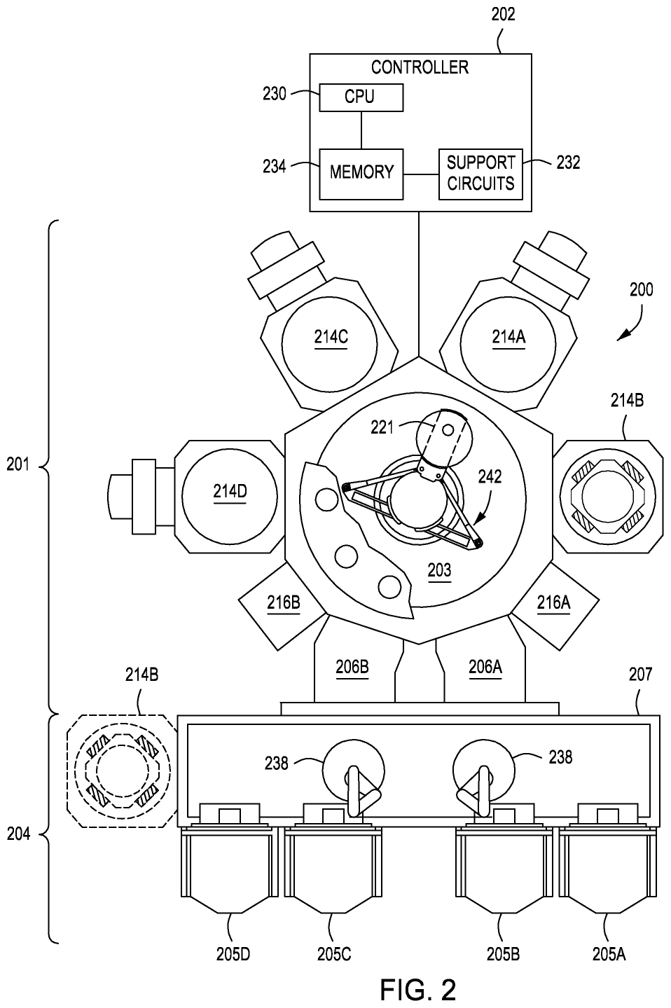

FIG. 1 is a flowchart of a method 100 for processing a substrate, and FIG. 2 is a tool 200 (or apparatus) that can be used for carrying out the method 100, in accordance with at least some embodiments of the present disclosure.

The method 100 may be performed in the tool 200 including any suitable process chambers, such as a deposition apparatus, a cleaning apparatus, an optional baking apparatus, a high pulse frequency laser trimming apparatus, a plasma etch apparatus, such as a reactive ion (plasma) etching apparatus, and related wafer transfer apparatus. Exemplary processing systems that may be used to perform the inventive methods disclosed herein may include, but are not limited to, certain processing tools commercially available from Applied Materials, Inc., of Santa Clara, Calif. Other process chambers, including those from other manufacturers, may also be suitably used or modified for use in accordance with the teachings provided herein.

The tool 200 can be embodied in individual process chambers that may be provided in a standalone configuration or as part of a cluster tool, for example, a tool 200 (integrated tool) described below with respect to FIG. 2. The methods described herein may be practiced using other cluster tools having suitable process chambers coupled thereto, or in other suitable process chambers. For example, in some embodiments, the inventive methods discussed above may be performed in an integrated tool such that there are requirements of an inert gas environment or limited or no vacuum breaks between processing steps. For example, reduced vacuum breaks may limit or prevent contamination (e.g., oxidation) of a tungsten liner layer or other portions of the substrate or prevent contamination (e.g., oxidation) of a backend of line copper, aluminum, or other portions of a substrate.

The Integrated tool includes a processing platform 201 (vacuum-tight processing platform), a factory interface 204, and a system controller 202. The processing platform 201 comprises multiple process chambers, such as 214A, 214B, 214C, and 214D operatively coupled to a transfer chamber 203 (vacuum substrate transfer chamber). The factory interface 204 is operatively coupled to the transfer chamber 203 by one or more load lock chambers (two load lock chambers, such as 206A and 206B shown in FIG. 2).

In some embodiments, the factory interface 204 comprises a docking station 207, a factory interface robot 238 to facilitate the transfer of one or more semiconductor substrates (wafers). The docking station 207 is configured to accept one or more front opening unified pod (FOUP). Four FOUPS, such as 205A, 205B, 205C, and 205D are shown in the embodiment of FIG. 2. The factory interface robot 238 is configured to transfer the substrates from the factory interface 204 to the processing platform 201 through the load lock chambers, such as 206A and 206B. Each of the load lock chambers 206A and 206B have a first port coupled to the factory interface 204 and a second port coupled to the transfer chamber 203. The load lock chamber 206A and 206B are coupled to a pressure control system (not shown) which pumps down and vents the load lock chambers 206A and 2068 to facilitate passing the substrates between the vacuum environment (or an inert gas environment) of the transfer chamber 203 and the substantially ambient (e.g., atmospheric) environment of the factory interface 204. The transfer chamber 203 has a vacuum robot 242 disposed within the transfer chamber 203. The vacuum robot 242 is capable of transferring substrates 221 between the load lock chamber 206A and 206B and the process chambers 214A, 2148, 214C, and 214D, which are coupled to the transfer chamber 203. Depending on a process that the process chambers 214A, 214B, 214C, and 214D are configured to perform, the process chambers 214A, 214B, 214C, and 214D can be vacuum chambers or atmospheric chambers.

The process chamber 214A comprises at least one deposition apparatus such as an atomic layer deposition apparatus, a chemical vapor deposition apparatus, a physical vapor deposition apparatus, an e-beam deposition apparatus, and/or an electroplating, electroless (EEP) deposition apparatus. The deposition apparatus of the process chamber 214A is configured to deposit a coating layer (e.g., a photoresist coating or etch mask that functions as a protection layer) on stacking layers of a substrate. Alternatively, in at least some embodiments, the coating layer can be applied via one or more conventional spin coating apparatus (or spray coating apparatus) and processes. For example, after the coating material is dispensed onto the substrate, the substrate can be rotated (spun) to disperse the coating material uniformly (e.g., a certain thickness) along the substrate. In such embodiments, the spin coating process can be performed via one or more atmospheric chambers, as described below.

An optional baking process can be performed to dry the coating layer. For example, the inventors have found that drying the coating layer 308 facilitates collecting debris, serves as an etch mask to protect the substrate during etching (e.g. a plasma etch process), and enhances energy coupling during 102. Accordingly, in at least some embodiments, the processing chamber 214A can include or be configured as a coating and baking apparatus. Alternatively, the baking process can be performed by a different processing chamber, such as a remote or stand-alone processing chamber (not shown). Additionally, the processing chamber 214A can be configured to remove the coating layer after the substrate has been fully processed. Accordingly, the processing chamber 214A can include or be configured to perform a wet etching process. Alternatively, the removing process can be performed by a different processing chamber, such as using the removing apparatus (e.g., process chamber 214D), as described below.

The process chamber 214B comprises at least one edge trimming apparatus that is configured to trim an edge of a top layer of the stacking layers. In at least some embodiments, the edge trimming apparatus of the process chamber 214B can be, for example, a high pulse frequency laser (e.g., for performing a high pulse frequency laser process) that is movable along at least one of an x-axis, a y-axis, or a z-axis. In at least some embodiments, the edge trimming apparatus can include a fixed high pulse frequency laser (e.g., stationary) and a movable substrate support that is moveable along at least one of an x-axis, a y-axis, or a z-axis. In at least some embodiments, the edge trimming apparatus can include a high pulse frequency laser that is movable along at least one of an x-axis, a y-axis and a movable substrate support that is movable along an x-y plane rotation and movable along a z-axis. Unlike the process chambers 214A, 214C, and 214D, which are vacuum chambers, the process chamber 214B can be an atmospheric chamber. Thus, in some embodiments, the process chamber 214B can be connected directly to docking station 207. In such embodiments, the process chamber 214B can be configured to perform a spin coating or spray coating process, e.g., to deposit the coating layer on a substrate.

The process chamber 214C comprises at least one etching apparatus that is configured to etch an edge (e.g., a far edge, such as about 2 mm to about 5 mm from a peripheral edge of a substrate) of a bottom layer and the stacking layers. In at least some embodiments, the etching apparatus of the process chamber 214C can be, for example, a reactive ion (plasma) etch apparatus.

The process chamber 214D comprises at least one removal apparatus that is configured to remove the coating layer from the stacking layers. In at least some embodiments, the removal apparatus can be, for example, a plasma-based sputter etching apparatus, a plasma based stripping apparatus, a wet chemical stripping and cleaning apparatus, such as a wet chemical stripping apparatus available from Applied Materials, Inc., of Santa Clara, Calif.

In some embodiments, one or more optional service chambers (shown as 216A and 216B) may be coupled to the transfer chamber 203. The service chambers 216A and 216B may be configured to perform one or more of the above described processes or other substrate processes, such as degassing, bonding, chemical mechanical polishing (CMP), wafer cleaving, plasma etching, plasma dicing (substrate singulation), orientation, substrate metrology, cool down and the like.

The system controller 202 controls the operation (e.g., to perform the method 100) of the tool 200 using a direct control of the process chambers 214A, 214B, 214C, and 214D or alternatively, by controlling the computers (or controllers) associated with the process chambers 214A, 214B, 214C, and 214D and the tool 200. In operation, the system controller 202 enables data collection and feedback from the respective chambers and systems to optimize performance of the tool 200. The system controller 202 generally includes a central processing unit (CPU) 230, a memory 234, and a support circuit 232. The CPU 230 may be any form of a general-purpose computer processor that can be used in an industrial setting. The support circuit 232 is conventionally coupled to the CPU 230 and may comprise a cache, clock circuits, input/output subsystems, power supplies, and the like. Software routines, such as processing methods as described above may be stored in the memory 234 (e.g., a non-transitory computer readable storage medium having stored thereon instructions for processing a substrate) and, when executed by the CPU 230, transform the CPU 230 into a system controller 202 (specific purpose computer). The software routines may also be stored and/or executed by a second controller (not shown) that is located remotely from the tool 200.

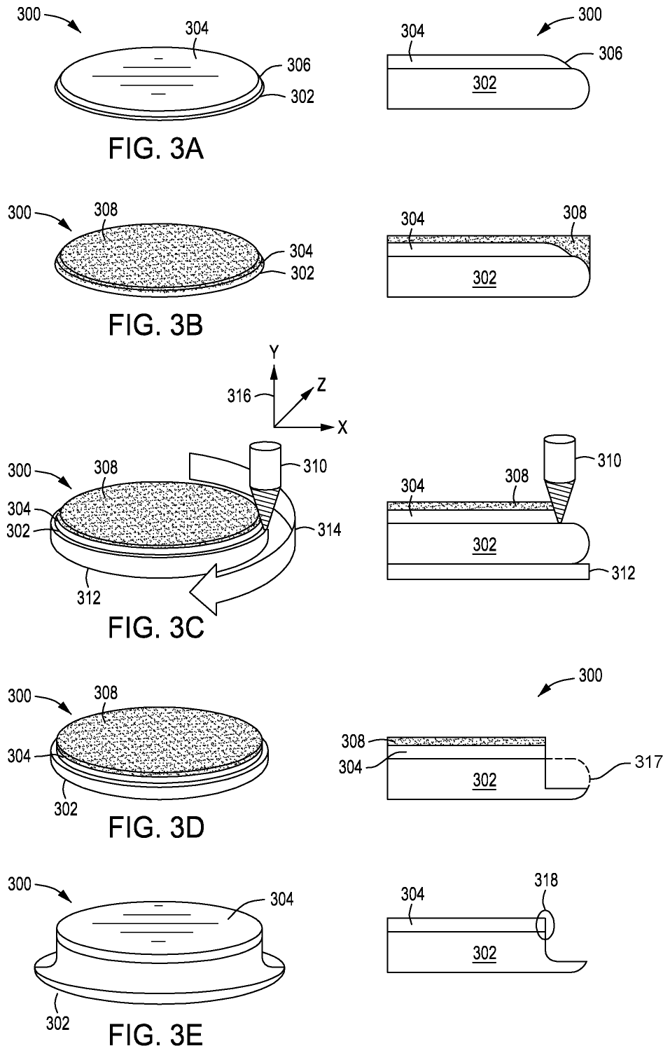

Continuing with reference to FIG. 1, and with reference to FIGS. 3A-3E, initially one or more substrates may be loaded into one or more FOUPS, such as one of the four FOUPS 205A, 205B, 205C, and 205D of the tool 200 (FIG. 2). For example, in at least some embodiments, a substrate 300 (e.g., an end process substrate, with functional transistors FEOL, BEOL, and final passivation) can be loaded into FOUP 205A. The substrate 300 can comprise a substrate having a suitable geometry, such as a semiconductor wafer (e.g., a 150 mm, 200 mm, 300 mm, 450 mm, or the like diameter wafer). The substrate 300 can comprise a bottom layer 302, which can be formed from one or more suitable materials, e.g., silicon, germanium, glass, or metal substrate made from copper, stainless steel, and/or aluminum (FIG. 3A). In at least some embodiments, the bottom layer 302 can be formed of silicon (e.g., a bottom layer of silicon). Stacking layers 304 (e.g., active layers, such as a plurality of integrated circuits, functional transistors, and the like) are disposed atop the bottom layer 302. The stacking layers 304 can comprise a low-k dielectric layer(s) such as extreme low-k (ELM) and/or ultralow-k (ULK) dielectric materials. An edge 306 (e.g., a far edge) of the stacking layers 304 can be relatively straight (e.g., perpendicular to a top surface of the bottom layer 302) or beveled (angled) relative to the top surface of the bottom layer 302. In the illustrated embodiment, the edge 306 of the stacking layers 304 is shown beveled.

Once loaded, the factory interface robot 238 can transfer the substrate 300 from the factory interface 204 to the processing platform 201 through, for example, the load lock chamber 206A. The vacuum robot 242 can transfer the substrate 300 from the load lock chamber 206A to and from one or more of the process chambers 214A-214D and/or the service chambers 216A and 216B.

For example, in at least some embodiments, the substrate 300 can be transferred to a process chamber for optionally depositing a coating layer 308 on the substrate 300 (FIG. 3B). The coating layer 308 can completely cover the upper surface of the substrate 300 and all layers disposed on the substrate 300 (e.g., atop the bottom layer 302 and stacking layers 304). The coating layer 308 can be deposited via one or more of the above described deposition apparatus, e.g., one of performing physical vapor deposition, chemical vapor deposition, atomic layer deposition, or a spin coating process. For example, in at least some embodiments, the substrate 300 can be transferred to the process chamber 214A so that one or more materials (e.g., a photoresist coating or etch mask that functions as a protection layer) can be deposited on the substrate via a suitable process such as PVD, spin coating, spray coating, or the like, to form the coating layer 308. In such embodiments, the substrate 300 can be transferred to the process chamber 214B.

When the coating layer 308 is deposited via spin coating or spray coating, the coating layer 308 can be formed using any material suitable for providing a protection coating for the bottom layer 302 and/or the stacking layers 306 as a trimming process is being performed on the substrate 300. For example, in at least some embodiments, the coating layer 308 can be made from an organic resin-based material that is solvent soluble. For example, in at least some embodiments, the coating layer 308 can be formed from at least one of polyvinyl alcohol, polyvinyl pyrrolidone, polyethylene glycol with oxyethylene recurring units, polyethylene oxide, methylcellulose, ethylcellulose, hydroxypropyl cellulose, polyacrylic acid, polyvinyl alcohol-polyacrylic acid block copolymer, polyvinyl alcohol-polyacrylic acid ester block copolymer, and polyglycerin. The coating layer 308 can be deposited atop the bottom layer 302 and/or the stacking layers 304 to a thickness of about 200 μm to about 2000 μm. As noted above, in at least some embodiments, the substrate 300 can be spin coated or spray coated to achieve a uniform or substantially uniform thickness of the coating layer 308 on the bottom layer 302 and/or the stacking layers 304.

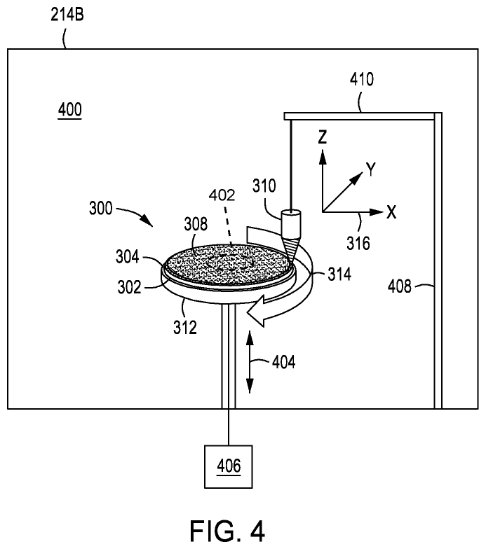

After the coating layer 308 is, optionally, deposited at 102, the substrate 300 can be transferred from the process chamber 214A to the process chamber 214B for trimming an edge (e.g., a far edge, such as about 2 mm to about 5 mm from a peripheral edge of a substrate) of the bottom layer 302 and the stacking layers 304, as illustrated in FIG. 3C. FIG. 4 is a diagram of an interior volume 400 of an exemplary embodiment of the process chamber 214B. In the illustrated embodiment, the edge trimming apparatus of the process chamber 214B can be a high pulse frequency laser 310 that is movable along at least one of an x-axis, a y-axis, or a z-axis, as illustrated by directional arrow 316 (as described above). In some embodiments, the high pulse frequency laser 310 can be coupled to a robot 408 including an arm 410 configured to move the high pulse frequency laser 310 along at least one of the x-axis, y-axis, or z-axis. For example, in some embodiments, the high pulse frequency laser 310 is movable along all three axes (i.e., the x-axis, the y-axis, and the z-axis). In some embodiments, the high pulse frequency laser 310 is movable within the x-y plane (i.e., along the x-axis and the y-axis).

The process chamber 214B comprises a substrate support 312, which can be a rotatable substrate support. The substrate support 312 can include a chucking electrode 402 for providing a chucking force to a backside of the substrate 300. Alternatively, or additionally, the substrate support 312 can couple to a vacuum source 406 for providing a vacuum clamping force to the backside of the substrate 300, e.g., while the substrate support 312 rotates, as illustrated by directional arrow 314. The substrate support 312 can also move up and down along the z-axis, as shown by bi-directional arrow 404. In at least some embodiments, the high pulse frequency laser 310 can be maintained in a fixed configuration as the substrate support 312 is rotated (e.g., clockwise or counterclockwise directions) to perform the edge trimming process. In at least some embodiments, the high pulse frequency laser 310 can be moved along at least one of the x-axis, the y-axis, or the z-axis as the substrate support 312 is rotated to perform the edge trimming process. In at least some embodiments, the high pulse frequency laser 310 can be moved along the x-axis and the y-axis (and optionally the a z-axis) as the substrate support 312 is maintained in a fixed configuration (e.g., not rotated) to perform the edge trimming process. After 102, little to no coating layer 308 will be present on the bottom layer 302, but the coating layer 308 will substantially remain on the stacking layers 304.

Next, 104, the substrate 300 can be transferred from the process chamber 214B to the process chamber 214C for etching an edge (edge 317 shown in phantom in FIG. 3D, which can be about 2 mm to about 5 mm from a peripheral edge) of the bottom layer 302. For example, in at least some embodiments the process chamber 214C can comprise a plasma or reactive ion etch (RIE) apparatus or a decoupled plasma source (DPS) apparatus that is configured to perform a plasma-based etch process to etch the bottom layer 302, without removing any (or a minimal amount) of the stacking layers 304 and the coating layer 308, and with minimal or no stress being applied to the stacking layers 304. For example, in at least some embodiments, a halogen containing etchant gas can be used to etch the bottom layer (silicon). Typically, a fluorine-based etchant gas, such as SF₆, can be used in a cyclic Bosch etch process or non-Bosch etch process, with substrate temperature controlled using, for example, an electrostatic chuck or vacuum chuck with a set point of about −20° C. to about +20° C., and RF source power of about 2 kW to about 6 kW and RF bias power of about 1 kW. The coating layer 308 functions as a masking layer at 104 so that only some of the bottom layer 302 is removed along an outer edge of the substrate 300. After 104 the edges of the bottom layer 302 and the stacking layers 304 are substantially aligned, see area of detail 318 of FIG. 3E.

Next, at 106, in at least some embodiments, the substrate can, optionally, be transferred from the process chamber 214C to the process chamber 214D for removing any of the remaining coating layer 308 from the stacking layers 304, as illustrated in FIG. 3C. For example, in at least some embodiments, the process chamber 214D can comprise a removal apparatus that can be a plasma-based sputter etching apparatus or a plasma-based stripping apparatus. Alternatively, in at least some embodiments, such as when the coating layer is water soluble, the coating can be removed using deionized water. The removal effectiveness can be enhanced with a physical component such one or more of a mist nozzle, megasonic energy, or with an elevated temperature of about 30° C. to 80° C. For example, in at least some embodiments, the elevated temperature can be about 40° C. to 70° C. In accordance with the present disclosure, the removal apparatus is configured such that all of the remaining coating layer 308 is removed at 106 and does not impinge the stacking layers 304.

After the method 100 is performed, the substrate 300 can be further processed. For example, the vacuum robot 242 can transfer the substrate 300 from one or more of the process chambers 214A-214D to the service chambers 216A and 216B, e.g., to perform one or more degassing, bonding, chemical mechanical polishing (CMP), wafer cleaving, etching, plasma dicing, orientation, substrate metrology, cool down and the like. For example, in at least some embodiments, a substrate that has been processed using the method 100 can be bonded to another substrate that has also been processed using the method 100.

While the foregoing is directed to embodiments of the present disclosure, other and further embodiments of the disclosure may be devised without departing from the basic scope thereof.

1. An integrated tool for processing a silicon substrate, comprising:
a controller configured to control:
a vacuum substrate transfer chamber;
an edge trimming apparatus coupled to the vacuum substrate transfer chamber and comprising a high pulse frequency laser and substrate support, wherein at least one of the high pulse frequency laser or the substrate support are movable with respect to each other and configured to trim about 2 mm to about 5 mm from a peripheral edge of a substrate when disposed on the substrate support; and
a plasma etching apparatus coupled to the vacuum substrate transfer chamber and configured to etch silicon.

2. The integrated tool of claim 1, wherein the substrate support is rotatable and is an electrostatic chuck or a vacuum chuck.

3. The integrated tool of claim 1, wherein the high pulse frequency laser is movable along an x-axis, a y-axis, or a z-axis.

4. The integrated tool of claim 1, wherein the plasma etching apparatus is one of a plasma-based sputter etching apparatus or a plasma-based stripping apparatus.

5. The integrated tool of claim 1, wherein the controller is further configured to control:
an apparatus configured to apply a coating layer at least on the substrate; and
a removal apparatus configured to remove the coating layer from the substrate.

6. The integrated tool of claim 5, wherein the apparatus configured to deposit the coating layer is one of a physical vapor deposition apparatus, chemical vapor deposition apparatus, an atomic layer deposition apparatus, or a spin coating apparatus, and wherein the removal apparatus is a plasma-based sputter etching apparatus.

7. The integrated tool of claim 5, wherein the coating layer is formed from one of a photoresist coating, an etch mask, polyvinyl alcohol, polyvinyl pyrrolidone, polyethylene glycol with oxyethylene recurring units, polyethylene oxide, methylcellulose, ethylcellulose, hydroxypropyl cellulose, polyacrylic acid, polyvinyl alcohol-polyacrylic acid block copolymer, polyvinyl alcohol-polyacrylic acid ester block copolymer, or polyglycerin.

8-20. (canceled)

21. The integrated tool of claim 5, wherein the coating layer is formed from an organic resin-based material.

22. The integrated tool of claim 21, wherein the organic resin-based material is solvent soluble.

23. The integrated tool of claim 5, wherein the coating layer is water soluble, and wherein the coating layer is removed using deionized water.

24. The integrated tool of claim 5, wherein the coating layer is deposited to a thickness of about 200 μm to about 2000 μm.

25. The integrated tool of claim 1, wherein the high pulse frequency laser is maintained in a fixed configuration as the substrate support is rotated in one of clockwise or counterclockwise direction during the edge trimming process.

26. The integrated tool of claim 1, wherein the high pulse frequency laser is moved along at least one of an x-axis, a y-axis, or a z-axis as the substrate support is rotated to perform the edge trimming process.

27. The integrated tool of claim 1, wherein the high pulse frequency laser is moved along at least one of an x-axis, a y-axis, or a z-axis as the substrate support is not rotated to perform the edge trimming process.

28. The integrated tool of claim 1, wherein the controller is further configured to control the integrated tool to process a substrate that is an end process substrate, with functional transistors FEOL, BEOL, and final passivation.

29. The integrated tool of claim 1, wherein the controller is further configured to control the integrated tool to process a substrate that comprises a bottom layer, which can be formed from at least one silicon, germanium, glass, or metal made from at least one of copper, stainless steel, or aluminum.

30. The integrated tool of claim 29, wherein stacking layers are disposed atop the bottom layer.

31. The integrated tool of claim 30, wherein the stacking layers comprise at least one of a plurality of integrated circuits or functional transistors.

32. The integrated tool of claim 30, wherein the stacking layers comprise a low-k dielectric layer.

33. The integrated tool of claim 32, wherein the low-k dielectric layer comprises at least one of an extreme low-k (ELM) dielectric material or ultralow-k (ULK) dielectric material.
